(19) United States
(12) Patent Application Publication
(10) Pub. No.: US 2012/0212904 A1
(43) Pub. Date: Aug. 23, 2012

(54) FLEXIBLE CIRCUITS AND SUBSTRATES COMPRISING VOLTAGE SWITCHABLE DIELECTRIC MATERIAL

(76) Inventors: Robert Fleming, San Jose, CA (US); Lex Kosowsky, San Jose, CA (US); Junjun Wu, Los Gatos, CA (US)

(21) Appl. No.: 13/358,506

(22) Filed: Jan. 25, 2012

Related U.S. Application Data
(63) Continuation-in-part of application No. 12/370,589, filed on Feb. 12, 2009.
(60) Provisional application No. 61/028,187, filed on Feb. 12, 2008.

(51) Int. Cl. H05K 1/03

(52) U.S. Cl. 361/679.56; 174/254

(57) ABSTRACT

Embodiments described herein provide for flexible circuits and flexible substrates comprising VSD material that has superior characteristics for its use as an integral structural component of a device.

### RELATED APPLICATIONS

This application is a continuation in part of U.S. patent application Ser. No. 12/370,589, titled “Voltage Switchable Dielectric Material With Superior Physical Properties for Structural Applications”, filed Feb. 12, 2009, which claims benefit of priority to Provisional U.S. Patent Application No. 61/028,187, titled “Voltage Switchable Dielectric Material With Superior Physical Properties”, filed Feb. 12, 2008; each of the aforementioned applications is incorporated by reference herein in its entirety.

### FIELD OF ART

This application relates to flexible substrates incorporating voltage switchable dielectric materials.

### BACKGROUND

Voltage switchable dielectric materials, also denoted “VSD materials” or “VSDM,” are known to be materials that are insulative at low voltages and conductive at higher voltages. These materials are typically composites comprising of conductive, semiconductive, and insulative particles in an insulative polymer matrix. Applications of these materials include transient protection of electronic devices, most notably electrostatic discharge protection (ESD) and electrical overstress (EOS). Generally, VSD material behaves substantially as a dielectric, unless a voltage exceeding a characteristic voltage is applied, in which case it behaves substantially as a conductor. Various kinds of VSD material exist. Examples of voltage switchable dielectric materials are provided in references such as U.S. Pat. No. 4,977,357, U.S. Pat. No. 5,068,634, U.S. Pat. No. 5,099,380, U.S. Pat. No. 5,142,263, U.S. Pat. No. 5,189,387, U.S. Pat. No. 5,248,517, U.S. Pat. No. 5,807,509, WO 96/02924, and WO 97/26665, all of which are incorporated by reference herein.

VSD materials may be formed using various processes and materials or compositions. One conventional technique provides that a layer of polymer is filled with high levels of conductive particles to very near the percolation threshold, typically more than 20% by volume. Semiconductor and/or insulator materials are then added to the mixture.

Another conventional technique provides for forming VSD material by mixing doped metal oxide powders, then sintering the powders to make particles with grain boundaries, and then adding the particles to a polymer matrix to above the percolation threshold.

### BRIEF DESCRIPTION OF THE DRAWINGS

FIG. 1 illustrates use of select VSD material in a core layer structure, under an embodiment.

FIG. 2 illustrates a formulation of VSD material, under an embodiment.

FIG. 3A and FIG. 3B each illustrate different configurations for a substrate device that is configured with VSD material having a composition such as described with any of the embodiments provided herein.

FIG. 4 is a simplified diagram of an electronic device on which VSD material in accordance with embodiments described herein may be provided.

### DETAILED DESCRIPTION

Embodiments described herein provide for VSD material that has superior characteristics for its use as an integral structural component of a device.

Traditionally, VSD Materials are polymer composites filled to more than 50% by volume of a particle filler. In order to provide a composite with some level of mechanical stability, some conventional approaches have used polymers with very low glass transition temperature (Tg) as a matrix material. Traditionally, the matrix has been formulated from silicone rubber, which provides reduced mechanical stability to the composite, low modulus of elasticity, low Tg, high CTE, and poor adhesion to metal and prepregs used in PCB laminates.

VSD materials are typically used in discrete device applications where the packaging of the device can provide the necessary mechanical properties. When a VSD material is used in an application in which it is an integral structural component of a device, such as a printed circuit board (PCB) or IC chip substrate, embodiments recognize that the physical property demands on the VSD material are higher than other usages. Accordingly, embodiments recognize that properties such as the modulus of elasticity, Tg, CTE, and the material's ability to adhere to metal foil and prepreg laminate materials become highly relevant when the VSD material becomes an integral structural component.

For product integration, it is also important that common adhesives can adhere to the VSD material. Silicone polymers lack the inherent property that enables adhesives to adhere to the material. With embodiments described herein, the matrix of the VSD material may be formulated to enable adhesion by common adhesives in manufacturing processes for various structures.

Under many conventional approaches, VSD material formulations have relied on silicone polymer based resins for use as a matrix. Silicones are resistant to reductive chemical side reactions during the current flow in the “on state” of conduction, which helps the electrical durability. Embodiments recognize that silicone resins, however, promote characteristics of VSD material (when formed from such resins) that lack structural integrity and impede structural applications. For example, silicone based resins have low Tg, high coefficient of thermal expansion and poor adhesive properties (not easy to stick too). When considered structurally, such resins make poor candidates for use as the matrix in VSD material for applications that embed layers in printed circuit boards or chip package substrates. Conversely, traditional circuit board materials such as epoxies, polyimides, polyurethanes, bismaleimides, and the like have great physical properties but are not resistive to reductive reactions during a high voltage pulse.

As an enhancement, one or more embodiments combine silicone polymer and organic (e.g. thermosetting) polymer in the form of a block or graft copolymer structure of silicone and epoxy and/or polymide and/or bismaleimide and/or cyanate ester. The block or graft copolymer may be used to form the matrix for VSD material. When used for VSD material, such copolymer structures provide the VSD material with superior properties that are suited for structural applications, such as those applications that require VSD material to adhere to metal (e.g. copper). The superior properties that result from use of such copolymers signify the ability of VSD material, formed from materials such as described, to remain structurally sound and uniformly disposed after the completion of the manufacturing processes that require its integration as a layer adhered to copper or other metal. For example, the VSD material with desired physical and electrical characteristics can optimally withstand temperature variation and stress induced by processes to laminate or form copper foil or other structures.

As mentioned, the use of block or graft copolymers enhance the desired properties of VSD material for structural applications. The copolymer may be in the form of a block copolymer, in which different sets of homopolymer subunits are linked in one chain. As an alternative, some embodiments of VSD material may employ graft copolymers for the matrix. Graft copolymers are a special type of branched copolymer in which the side chains are structurally distinct from the main chain. Embodiments referenced herein that utilize block copolymers may alternatively use graft copolymers.

When a VSD material is used in an application in which it is an integral structural component of the system, such as a printed circuit board (PCB) or IC chip substrate, embodiments recognize that the physical property demands on the VSD material are higher than other usages. Various applications for VSD material are depicted below.

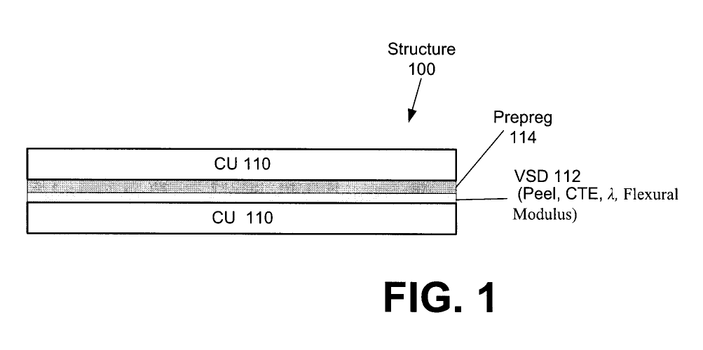

FIG. 1 illustrates use of select VSD material in a core layer structure, under an embodiment. The core layer structure 100 illustrates one application of VSD material where superior physical characteristics of the VSD material are beneficial. In an embodiment, the core layer structure 100 includes one layer of conductive foil 110 coated with protective VSD material 112. In some implementations, prepreg material 114 may overlay VSD material 112. The core layer. structure enables use of VSD material 112 as a functional layer embedded into a printed circuit board or other substrate device. The VSD material 112 is adhered to one of the foils. The prepreg layer 114 may be distributed between one of the layers of foil and the VSD material 112. Numerous other variations to the core layer structure 100 are possible. For example, additional layers of the materials as depicted may be implemented. Structural variations may also be included in the layers that comprise the core layer structure, or in the structure 100 as a whole (e.g. presence of vias). In any of the context described, embodiments provide for the use of VSD material with superior properties to enhance the integrity and formation of VSD material on the structure. These superior properties may be classified as relating to structural integrity and electrical durability.

Structural Integrity: VSD material is typically deposited as a layer on site (e.g. on a copper foil), then cured. In contrast to many past approaches, embodiments described herein provide for VSD material that is deposited as a layer having uniform thickness on a copper or conductive foil, where it is adhered. Because of its superior physical properties, subsequent manufacturing processes, such as lamination, copper etching/patterning processes, and heat treatments, do not substantially affect the uniformity of the VSD material. More specifically, the VSD material, in formulations such as described by embodiments, adheres and remains uniformly disposed as a layer on the substrate device after performance of various manufacturing processes (such as lamination or processes that affect temperature). When laminated to flexible substrates the VSD material layer is substantially flexible as well.

Electrical durability: Electrical durability refers to the characteristic that the VSD material does not substantially degrade electrical performance after an initial transient electrical event that causes at least some of the material to become conductive. Desirable electrical durability may specifically be quantified by the material's leakage current (i) after an initial electrical event, and (ii) in presence of some electrical stress. In an embodiment, VSD material is provided with electrical durability that is quantified, after an initial transient event that causes the VSD material to become conductive, to be no greater than 1 milliamp leakage, with application of voltage in range of 1 to 12 volts subsequent to the initial transient event. According to one embodiment, the electrical durability is quantified to be less than 1 milliamp leakage and in the range of 0.1 milliamps or less with application of voltage in the range of 1 to 12 volts. A technique for defining a standard by which electrical durability is determined herein is described below.

Accordingly, VSD material may be formulated to provide specific properties that are known to materials in order to enhance structural integrity, flexibility, adhesion, electrical durability and other desired characteristics. Using, for example, properties of the matrix material and/or particle constituents, the VSD material may be formulated to exhibit numerous specific and known characteristics of materials. These characteristics may directly or indirectly relate to electrical durability and integrity. According to some embodiments, these characteristics include one or more of the following properties: (i) Peel: adhere sufficiently to the copper foil (for purpose of this application, good adherence can be assumed to occur when the VSD material has peel that is greater than 3 lb/inch peel); (ii) thermal expansion coefficient (CTE): have a sufficiently low CTE so as to sustain various manufacturing processes that occur in formulating the core layer structure 100; (iii) have a high modulus of elasticity and flexural elasticity, and (iv) have high thermal stability (i.e. passes lead-free solder reflow conditions).

In an embodiment, the VSD material 112 is designed to have sufficiently low CTE to enable the VSD material to withstand delamination or other processes that are performed with extreme temperature fluctuations. The VSD material 112 may also be designed to have high flexural strength such that it does not crack during the manufacturing process and use of the structure 100 or finished PCB.

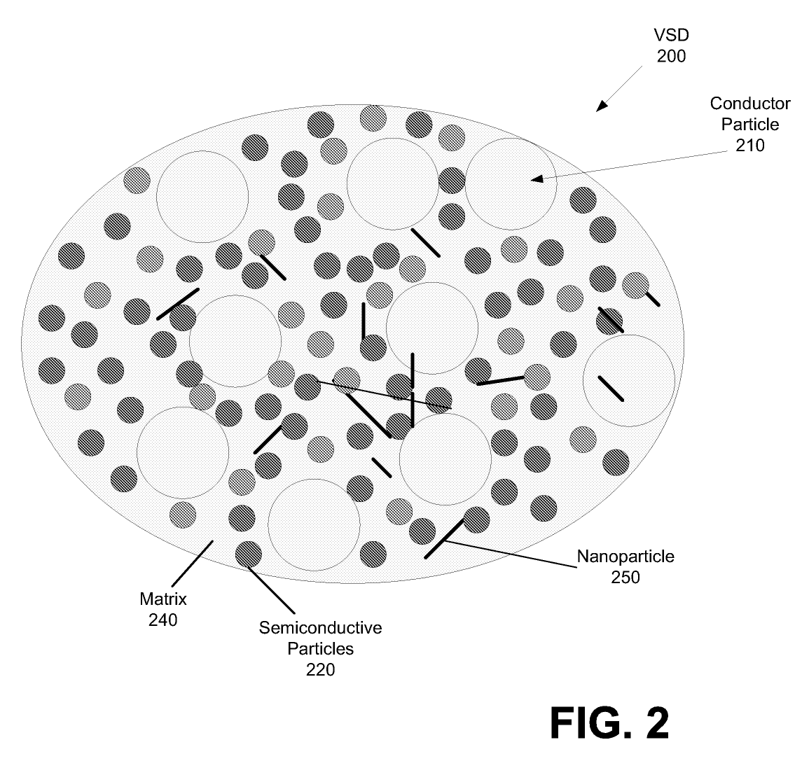

FIG. 2 illustrates a formulation of VSD material, under an embodiment. The formulation may include various constituents that individually or collectively combine to provide desired properties such as described with an embodiment of FIG. 1. In an embodiment such as shown, VSD material 200 includes particle constituents dispersed in a binder or matrix 240. The particle constituents may vary, depending on design and composition of VSD material. According to various embodiments, the particle constituents correspond or are composed of (i) a concentration of conductor particles 210, (ii) a concentration of semiconductor particles 220, and/or (iii) a concentration of nano-dimensioned particles. The concentration of nano-dimensioned particles may correspond to organic particles (such as graphenes, single wall carbon nanotubes or multi-wall carbon nanotubes) or inorganic high aspect ratio (HAR) particles (nanorods, nanowires etc.). Various types of VSD material are possible, with some or all of the different types of particle constituents listed. For example, in one embodiment, the VSD material 200 is comprised of a concentration of conductor particles (e.g. nickel and/or tungsten) without use of semiconductor particles or nano-dimensioned particles. In another embodiment, conductor particles and semiconductive particles 220 may be dispersed in the matrix 240. Still further, nano-dimensioned particles may be added to the matrix as an option. Some embodiments that emphasize use of conductor particles 210 load particle constituents to below, or just below the percolation threshold of the matrix 240. Other embodiments use semiconductive particles 220 (with or without conductor particles 210) and/or nano-dimensioned particles (which can be conductors or semiconductors, depending on the type of particle used) to load the particle concentration past the percolation threshold.

In one embodiment, the matrix 240 is formed from a copolymer, such as a block copolymer or graft polymer. The particle constituents include metal conductors, and the overall particle concentration is below (or just below) the percolation threshold. According to some embodiments, a composition of VSD material includes 15-30% by volume of micron sized conductors, 0.1-10% by volume of nano-sized conductors, 0-20% by volume of micron-sized semiconductors and 5-30% by volume of nano-sized semiconductors. Such formulations, with appropriately selected particles, enable development of VSD material with one or more of the properties as stated. Some superior physical characteristics may be provided in part by the selection of the type and quantity of nanoparticles. Numerous compositions of VSD materials in accordance with embodiments described herein are described with FIG. 1.

Various stepped band-gap compositions of VSD materials are described in U.S. patent application Ser. No. 12/953,309, titled “Formulations for Voltage Switchable Dielectric Materials Having a Stepped Voltage Response and Methods for Making the Same,” and filed on Nov. 23, 2010, and in US. Pat. No. 7,872,251, titled “Formulations for voltage switchable dielectric material having a stepped voltage response and methods for making the same.” Various relatively-low band-gap compositions of VSD materials are described in U.S. patent application Ser. No. 12/407,346, titled “Voltage Switchable Dielectric Materials with Low Band Gap Polymer Binder Or Composite,” and filed on Mar. 19, 2009. The Ser. No. 12/953,309 application, U.S. Pat. No. 7,872,251 patent and Ser. No. 12/407,346 application are each incorporated herein by reference entirely.

Specific compositions and techniques by which organic and/or HAR particles are incorporated into the composition of VSD material are described in U.S. patent application Ser. No. 11/829,946, entitled VOLTAGE SWITCHABLE DIELECTRIC MATERIAL HAVING CONDUCTIVE OR SEMI-CONDUCTIVE ORGANIC MATERIAL; and U.S. patent application Ser. No. 11/829,948, entitled VOLTAGE SWITCHABLE DIELECTRIC MATERIAL HAVING HIGH ASPECT RATIO PARTICLES; both of the aforementioned patent applications are incorporated by reference in their respective entirety by this application.

A mixture of semiconductors that have been sintered to form micron sized particles could be added to the block copolymer resin with optional conductors to form a VSD material.

As mentioned, embodiments recognize that the matrix or binder 240 often is integral in the physical properties of the resulting VSD material. Accordingly, the matrix 240 is be selected to have specific properties or characteristics that promote, enhance or amplify the properties that are desired from the VSD material. In one embodiment, matrix 240 includes a copolymer material (such as an epoxy compound or other polymer material) that exhibits good adhesion to copper and also includes surfactants and surface treatments to enhance the compatibility and electrical properties of the nanoparticles (and/or micron sized particles) with the matrix polymer.

As mentioned, one or more embodiments enhance the VSD material by forming matrix 240 from a block or graft copolymer. In an embodiment, a block polymer for use as matrix 240 may be formed by combining two polymers using a curative. In one embodiment, a silicone polymer (“Block A”) (characterized by good electrical durability, and relatively poor metal adhesion) may be combined with, for example, a hydrocarbon polymer (“Block B”) (traditionally having poor electrical characteristics, but good adhesion to metal or copper) using a suitable curative. In one implementation, the silicone based polymer is combined with epoxy, using a curative such as of a diamine, phenolic, or anhydride types. The following may be used for Block A silicone and Block B (shown as polybutadiene):

“Block A” Silicone

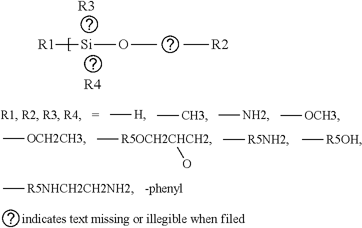

R5=—(CH2)x-
X=1 to 1000

“Block B” polybutadiene

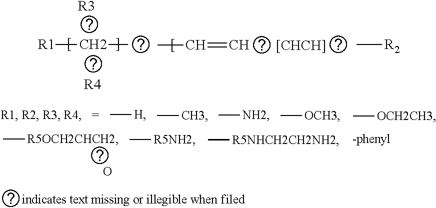

R5=—(CH2)x-
X=1 to 1000

Still further, the block copolymer may be formed from segments with low glass transition temperature (Tg) and segments with high Tg. In one embodiment, the copolymer includes one or more block copolymers, such as:

(1) Bisphenol A epoxy block-polybutadiene block-Bisphenol A epoxy block

In another embodiment, one or more block copolymers may be used, such as: (2) Bisphenol A epoxy block-polydimethyl siloxane block-Bisphenol A epoxy block

Still further, another embodiment may use: (3) Bisphenol A epoxy block-polydimethyl siloxane block-Bisphenol A epoxy block

(4) Polyimide block—polydimethyl siloxane block—polyimide block

Other block copolymers of the form ABA, BAB, AB, or BA can be used, where A=low Tg, and B=high Tg. The following are general examples of block copolymer formulations:

AAAAABBBBBCCCCC

AAAAABBBBAAAAA

BBBBBBCCCCCBBBBBDDDDD

The following is an example of a graft copolymer formulation with similarly defined blocks:

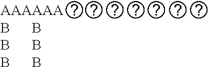

In the examples provided for block or graft copolymers, examples of the ‘C’ and ‘D’ blocks include:

“Block C” Polyimide

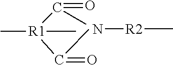

R1, R2=-phenyl, -biphenyl, hydrocarbon, or silicone

“Block D” Epoxy

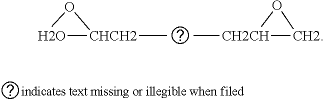

R=Bisphenol A, hydrogenated bisphenol A, cyclohexane
dimethanol, —CH2-
x=1 to 100
   The following structures are examples Block A, as provided with one or more bodiments.

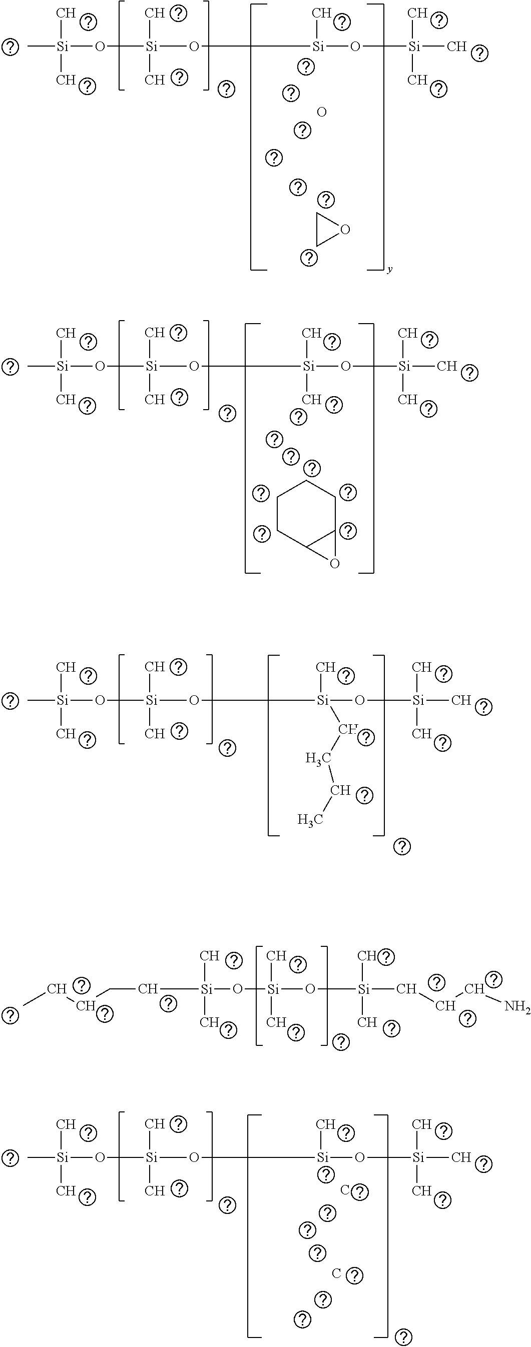

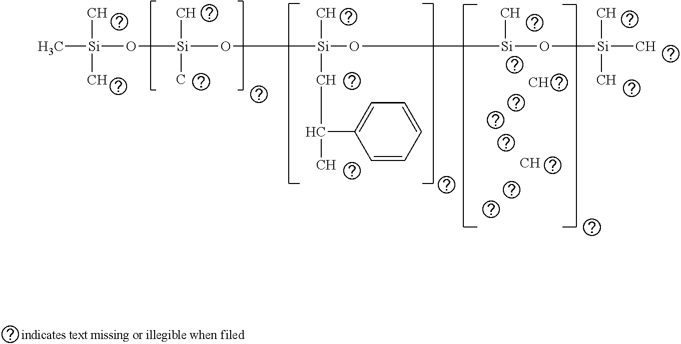

The following structures are examples Block B, as provided with one or more embodiments.

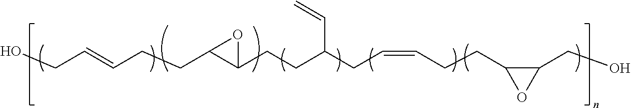

The following structures are examples Block D, as provided with one or more embodiments.

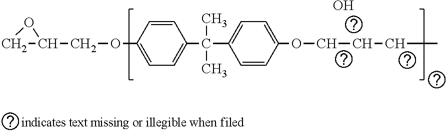

Table 1 describes various Formulations (listed columnularly) in accordance with various embodiments.

TABLE 1
Example Formulations.

| | Weight | Weight | Weight | | | Weight | Weight | Weight | Weight |
|---|---|---|---|---|---|---|---|---|---|
| | (grams) | (grams) | (grams) | Weight | Weight | (grams) | (grams) | (grams) | (grams) |
| | JW013- | PS017- | PS017- | (grams) | (grams) | RJF003- | RJF003- | RJF003- | PS017- |
| Material | 051 | 110 | 141 | RJF005-1 | RJF005-6 | 135 | 95 | 183 | 135 |
| Epon 828 | 157.0 | 49.2 | 114.4 | 90 | 23.25 | 0 | 15.1 | 0 | 158.4 |
| EP0409 | 0 | 0 | 0 | 22 | 21.05 | 0 | 0 | 0 | 0 |
| POSS | | | | | | | | | |
| Albiflex | 0 | 0 | 0 | 0 | 0 | 30.05 | 0 | 0 | 0 |
| 296 | | | | | | | | | |
| SIB1115 | 0 | 0 | 0 | 0 | 0 | 0 | 2.09 | 0 | 0 |
| epoxy | | | | | | | | | |
| silicone | | | | | | | | | |
| KJR651E | 0 | 0 | 0 | 0 | 0 | 0 | 0 | 205.1 | 0 |
| Multiwall | 0 | 4.84 | 5.01 | 5.5 | 0 | 0 | 0 | 2.36 | 5.08 |
| Carbon | | | | | | | | | |
| Nanotubes | | | | | | | | | |
| 5% | 0 | | | | 71.1 | 0 | 0 | 0 | 0 |
| MWCNT | | | | | | | | | |
| in epoxy | | | | | | | | | |
| CP-1230 | 0 | 0 | 0 | 0 | 0 | 80.73 | 21.0 | 0 | 0 |
| MWCNT | | | | | | | | | |
| in epoxy | | | | | | | | | |
| Cabotherm | 0 | 0 | 0 | 21 | 23.11 | 34.09 | 0 | 10.11 | 0 |
| BN | | | | | | | | | |
| GP611 | 52.7 | 49.2 | 38.13 | 0 | 0 | 0 | 0 | 0 | 0 |
| KR44 | 0 | 2.57 | 2.61 | 0 | 0 | 0 | 0 | 0 | 2.71 |
| PolyBD | 0 | 49.2 | 0 | 0 | 0 | 0 | 0 | 0 | 0 |
| 605E | | | | | | | | | |
| Bismuth | 0 | 142.5 | 140.3 | 0 | 0 | 0 | 0 | 0 | 147.8 |
| Oxide | | | | | | | | | |
| Titanium | 0 | 84.4 | 83.9 | 215 | 197.1 | 158.06 | 0 | 80.01 | 87.8 |
| Dioxide | | | | | | | | | |
| DT52 | | | | | | | | | |
| Titanium | 109.4 | 77.9 | 77.4 | 0 | | 0 | 39.0 | 0 | 81.0 |
| Dioxide | | | | | | | | | |
| P25 | | | | | | | | | |
| Dyhard | 9.9 | 6.03 | 7.17 | 5.25 | 5.25 | 3.9 | 1.73 | 0 | 7.26 |
| T03 | | | | | | | | | |
| Nickel | 750.0 | 620.7 | 633.5 | 0 | 0 | 0 | 0 | 0 | 648.1 |
| 4SP-10 | | | | | | | | | |
| Nickel | 62.6 | 0 | 0 | 0 | 0 | 140.46 | 162 | 85.03 | 0 |
| INP400 | | | | | | | | | |
| 1- | 1.04 | 0.83 | 0.83 | 0.5 | 0.6 | 0.68 | 0.05 | 0 | 0.84 |
| methylimidazole | | | | | | | | | |
| HCTF | 0 | | | 120 | 117 | 68.5 | 0 | 45.03 | 0 |
| TiB2 | | | | | | | | | |
| Titanium | 0 | | | 112 | 113.16 | 0 | 0 | 0 | 0 |
| Nitride | | | | | | | | | |
| grade C | | | | | | | | | |
| N- | 151.8 | 194.2 | 160.6 | 269.8 | 355 | 233 | 109.8 | 150 | 116 |
| methylpyrrolidone | | | | | | | | | |
| FS10P | 34.8 | 0 | 0 | 0 | 0 | 0 | 0 | 0 | 0 |
| ATO rods | | | | | | | | | |
| UVLP7500 | 109.4 | 0 | 0 | 0 | 0 | 0 | 0 | 0 | 0 |
| TiO2 | | | | | | | | | |
| BYK 142 | 4.8 | 0 | 0 | 0 | 0 | 0 | 0 | 0 | 0 |

A general process for formulating VSD material in accordance with one or more embodiments: (i) Add MWCNT, polymers, NMP and predisperse with sonication 1 hour; (ii) Add surfactants/dispersants, curative, and catalyst; (iii) Add powders slowly while mixing with Cowles blade mixer; and (iv) Mix in high shear rotor-stator type mixer with sonication.

The following table shows example formulations of block copolymers containing silicone blocks and polyimide, epoxy, and/or polybutadiene blocks.

TABLE 2
Resulting physical and electrical properties.

| Peel | Pre Tg | Post Tg | | | Post electrical Stress |
|---|---|---|---|---|---|
| (lb/inch) | CTE | CTE | | Clamp | Leakage current |
| (kg/cm) | Ppm/C. | Ppm/C. | Tg C. | Voltage | at 3 volts |
| 3.8 (0.68) | 74 | 84 | 159 | 161 | 2.26E−7 |
| 3.28 (0.59) | 57 | 68 | 140 | 366 | 7.28E−8 |
| 3.08 (0.55) | 80 | 87 | 146 | 237 | 8.07E−8 |
| 4.42 (0.79) | | | 150 | 206 | 3.69E−6 |
| | | | | | (see PS017-135) |

The following table lists examples of materials that may be used as provided by supplier.

TABLE 3
Supplier Listing

| Material | Supplier |
|---|---|
| Epon 828 | Resolution Performance Products |
| EP0409 POSS | Hybrid Plastics |
| Albiflex 296 | Hanse chemie USA, Inc. |
| SIB1115 epoxy silicone | Gelest |
| KJR651E | Shin-Etsu |
| Multiwall Carbon Nanotubes | Cheaptubes |
| 5% MWCNT in epoxy | Zyvek |
| CP-1230 MWCNT in epoxy | Hyperion Catalysis |
| Cabotherm BN | Saint-Gobian Advanced Ceramics |
| | Corporation |
| GP611 | Genesee Polymers |
| KR44 | Kenrich Petrochemicals |
| PolyBD 605E | Sartomer |
| Bismuth Oxide | Nanophase |
| Titanium Dioxide DT52 | Millenium Chemical |
| Titanium Dioxide P25 | Evonik (Degussa) |
| Dyhard T03 | Evonik (Degussa) |
| Nickel 4SP-10 | Inco Novamet |
| Nickel INP400 | Inco Novamet |

Electrical Durability and Measurement Standard

Numerous embodiments described herein provide for formulation of VSD material that has enhanced electrical durability. As mentioned previously, desirable electrical durability properties of VSD material may be quantified in the following manner: For a given quantity of VSD material (i) after an initial transient event that causes the VSD material to become conductive, (ii) then while under electrical stress (as can be) measured by voltage in range of 1 to 12 volts subsequent to the initial transient event, (iii) the VSD material exhibits leakage current that is no greater than 1 milliamp. The standard for quantifying electrical durability as mentioned may correspond or be consistent with the following technique. A transmission line pulse (TLP) generator is used to generate a square-wave shaped pulse having very fast rise/fall times and a uniform amplitude throughout the duration of the pulse. This is accomplished by first charging a length of transmission line (for example, a coaxial cable, cut to give a 130 ns pulse width) to charged to 3000 volts (actual voltage discharged into sample is 900 Volts due to attenuation in the matching network) and then discharging the transmission line through a suitable matching network into the structure (i.e. layer of VSD material) being studied. The pulse width is proportional to the length of the transmission line, with longer lengths resulting in wider pulses and shorter lengths resulting in shorter pulses. The oscilloscope is connected to the structure being studied by way voltage probe. This allows one to study the response of the structure to the TLP pulse throughout the duration of the pulse.

VSD Materiald Applications

Numerous applications exist for compositions of VSD material in accordance with any of the embodiments described herein. In particular, embodiments provide for VSD material to be provided on substrate devices, such as printed circuit boards, semiconductor packages, discrete devices, thin film electronics, as well as more specific applications such as LEDs and radio-frequency devices (e.g. RFID tags). Still further, other applications may provide for use of VSD material such as described herein with a liquid crystal display, organic light emissive display, electrochromic display, electrophoretic display, or back plane driver for such devices. The purpose for including the VSD material may be to enhance handling of transient and overvoltage conditions, such as may arise with ESD events. Another application for VSD material includes metal deposition, as described in U.S. Pat. No. 6,797,145 to L. Kosowsky (which is hereby incorporated by reference in its entirety).

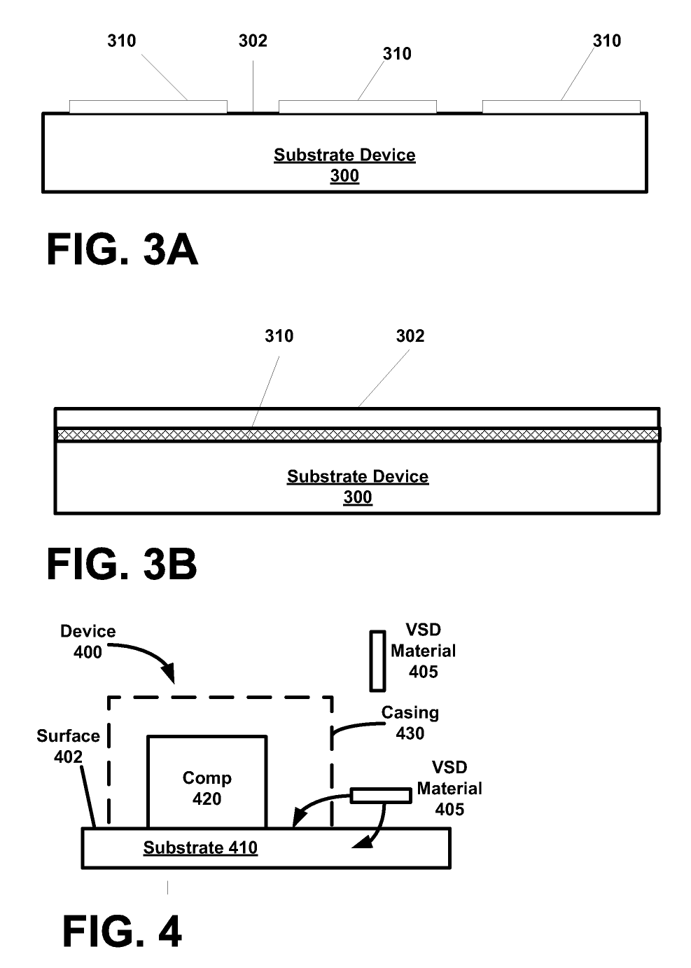

FIG. 3A and FIG. 3B each illustrate different configurations for a substrate device that is configured with VSD material having a composition such as described with any of the embodiments provided herein. In FIG. 3A, the substrate device 300 corresponds to, for example, a printed circuit board. In such a configuration, VSD material 310 (having a composition such as described with any of the embodiments described herein) may be provided on a surface 302 to ground a connected element. As an alternative or variation, FIG. 3B illustrates a configuration in which the VSD material forms a grounding path that is embedded within a thickness 310 of the substrate.

Electroplating

In addition to inclusion of the VSD material on devices for handling, for example, ESD events, one or more embodiments contemplate use of VSD material (using compositions such as described with any of the embodiments herein) to form substrate devices, including trace elements on substrates, and interconnect elements such as vias. U.S. patent application Ser. No. 11/881,896, filed on Sep. Jul. 29, 2007, and which claims benefit of priority to U.S. Pat. No. 6,797,145 (both of which are incorporated herein by reference in their respective entirety) recites numerous techniques for electroplating substrates, vias and other devices using VSD.material. Embodiments described herein enable use of VSD material, as described with any of the embodiments in this application.

Other Applications

FIG. 4 is a simplified diagram of an electronic device on which VSD material in accordance with embodiments described herein may be provided. FIG. 4 illustrates a device 400 including substrate 410, component 420, and optionally casing or housing 430. VSD material 405 (in accordance with any of the embodiments described) may be incorporated into any one or more of many locations, including at a location on a surface 402, underneath the surface 402 (such as under its trace elements or under component 420), or within a thickness of substrate 410. Alternatively, the VSD material may be incorporated into the casing 430. In each case, the VSD material 405 may be incorporated so as to couple with conductive elements, such as trace leads, when voltage exceeding the characteristic voltage is present. Thus, the VSD material 405 is a conductive element in the presence of a specific voltage condition.

With respect to any of the applications described herein, device 400 may be a display device. For example, component 420 may correspond to an LED that illuminates from the substrate 410. The positioning and configuration of the VSD material 405 on substrate 410 may be selective to accommodate the electrical leads, terminals (i.e. input or outputs) and other conductive elements that are provided with, used by or incorporated into the light-emitting device. As an alternative, the VSD material may be incorporated between the positive and negative leads of the LED device, apart from a substrate. Still further, one or more embodiments provide for use of organic LEDs, in which case VSD material may be provided, for example, underneath the OLED.

With regard to LEDs and other light emitting devices, any of the embodiments described in U.S. patent application Ser. No. 11/562,289 (which is incorporated by reference herein) may be implemented with VSD material such as described with other embodiments of this application.

Alternatively, the device 400 may correspond to a wireless communication device, such as a radio-frequency identification device. With regard to wireless communication devices such as radio-frequency identification devices (RFID) and wireless communication components, VSD material may protect the component 420 from, for example, overcharge or ESD events. In such cases, component 420 may correspond to a chip or wireless communication component of the device. Alternatively, the use of VSD material 405 may protect other components from charge that may be caused by the component 420. For example, component 420 may correspond to a battery, and the VSD material 405 may be provided as a trace element on a surface of the substrate 410 to protect against voltage conditions that arise from a battery event. Any composition of VSD material in accordance with embodiments described herein may be implemented for use as VSD material for device and device configurations described in U.S. patent application Ser. No. 11/562,222 (incorporated by reference herein), which describes numerous implementations of wireless communication devices which incorporate VSD material.

As an alternative or variation, the component 420 may correspond to, for example, a discrete semiconductor device. The VSD material 405 may be integrated with the component, or positioned to electrically couple to the component in the presence of a voltage that switches the material on.

Still further, device 400 may correspond to a packaged device, or alternatively, a semiconductor package for receiving a substrate component. VSD material 405 may be combined with the casing 430 prior to substrate 410 or component 420 being included in the device.

In various embodiments, a VSD material may be incorporated within a substrate, with the substrate being integrated in an electronic device. In such embodiments, the VSD material incorporated in the substrate may be used to provide ESD protection to the substrate itself, to circuit elements attached to substrate or incorporated within the substrate, to electronic components attached to the substrate, and/or to other portions of the electronic device.

From an operational perspective, a VSD material may be used within a substrate to perform an electrical switching function as part of a horizontal switching formation or as part of a vertical switching formation.

In various embodiments, a “horizontal switching VSD material formation” or “horizontal switching VSDM formation” is a structure comprising VSD material that is integrated in a substrate and is adapted to switch in a “horizontal” direction or “lateral” direction. This horizontal or lateral direction is defined relative to the substrate and indicates that the flow of electric current through the VSD material takes place predominantly in a direction substantially parallel with the main plane of the substrate. In one embodiment, a VSDM formation is formed such that the switching VSD material is disposed in a layer of a substrate (e.g., a layer of a PCB or of a flexible circuit), in which case horizontal switching means that the flow of electric current through the VSD material takes place predominantly in a direction substantially parallel with the main surface of the substrate.

In various embodiments, a VSD material may be used in a vertical switching VSD material formation, denoted a “vertical switching VSD material formation” or “vertical switching VSDM formation”. A vertical switching VSDM formation is generally integrated in a substrate to achieve vertical switching across the thickness of a layer of VSD material. A VSDM formation adapted to perform vertical switching generally comprises at least one layer of VSD material and two conductive elements disposed on the opposite sides of the VSD material layer such that electric current can propagate across the layer of VSD material.

Certain vertical switching VSDM formations were disclosed in U.S. patent application Ser. No. 12/417,589, filed on Apr. 2, 2009 by Shocking Technologies, Inc., and in U.S. patent application 61/537,490, filed on Sep. 21, 2011 by Shocking Technologies, Inc. Each of the Ser. No. 12/417,589 and 61/537,490 applications is incorporated herein by reference in its entirety.

When switching in response to a transient voltage that exceeds a characteristic voltage level, a horizontal switching VSDM formation switches across a horizontal (or lateral) gap formed by a layer of VSD material layer. When switching in response to a transient voltage that exceeds a characteristic voltage level, a vertical switching VSDM formation switches across a vertical thickness (or vertical gap) of a layer of VSD material layer.

Examples of substrates in which VSD materials may be incorporated in accordance with various embodiments, such as the structure 100 from the embodiment of FIG. 1, substrate device 300 from the embodiment of FIGS. 3A and 3B, and substrate 410 from the embodiment of FIG. 4, may include a PCB, any single layer or set of multiple layers of a PCB, the package of a semiconductor device (e.g., ball grid array (BGA), a land grid array (LGA), a pin grid array), an LED substrate, an integrated circuit (IC) substrate, an interposer or any other platform that connects two or more electronic components, devices or substrates (where such connection may be vertical and/or horizontal), any other stacked packaging or die format (e.g., an interposer, a wafer-level package, a package-in-package, a system-in-package, or any other stacked combination of at least two packages, dies or substrates), or any other substrate to which a VSD material formation can be attached or within which a VSD material formation may be incorporated.

Examples of electronic components that may be protected by VSD materials incorporated in substrates in accordance with various embodiments include one or more of the following: a semiconductor chip or another integrated circuit (IC) (e.g., a microprocessor, controller, memory chip, RF circuit, baseband processor, system on a chip (SOC), a flip chip, etc.), a light emitting diode (LED), an LED array, an LCD, LED, OLED or any other type of display, a MEMS chip or structure, or any other component or circuit element that is incorporated in an electronic device or is used to display information generated by an electronic device. An electronic component may consist of a single chip unit, or may comprise multiple die and/or stacked components that are packaged together or otherwise adapted to operate together.

Examples of electronic devices that may be protected VSD materials incorporated within substrate devices include mobile phones (e.g., a smartphone, a feature phone, a cordless phone), mobile communication devices (e.g., walkie-talkies, communication equipment used by emergency response personnel), electronic tablets, electronic readers (e-reader), mobile computers (e.g., a laptop), desktop computers, server computers (e.g., servers, blades, multi-processor supercomputers), television sets, video displays, music players (e.g., a portable MP3 music player), personal health management devices (e.g., a pulse monitor, a cardiac monitor, a distance monitor, a temperature monitor, or any other sensor device with applications in health management), light emitting diodes (LEDs) and devices comprising LEDs, lighting modules, and any other consumer and/or industrial devices that process or otherwise store data using electrical or electromechanical signals. Other examples include satellites, military equipment, aviation instruments, and marine equipment.

In various embodiments, a VSD material may be incorporated in a connector to provide ESD protection. Such a connector may be attached to an electronic device that could, benefit from protection against ESD or other overvoltage events. Examples of such connectors include a power connector, a USB connector, an Ethernet cable connector, an HDMI connector, or any other connector that facilitates serial, parallel or other types of data, signal or power transmission. In such an embodiment, a cable attached to such an electronic device could provide both its underlying functionality (e.g., data communications) and ESD protection.

In various embodiments, a VSD material may be incorporated in a flexible substrate (e.g., a flexible PCB, flexible semiconductor package, or flexible connector) In various embodiments, such flexible substrates may be manufactured out of polyimide materials, Teflon, epoxy-based materials, or other flexible hybrid materials. Polyimide materials are generally lightweight and flexible, have higher mechanical elongation and tensile strength, and tend to have improved resilience against heat and chemical reactions. Polyimide materials are used in the electronics industry to manufacture flexible electrical cables, as an insulating or passivation layer in the manufacture of digital semiconductor and MEMS chips, as insulating films, as high-temperature adhesives, for medical tubing applications, and for other applications where flexibility, lower weight and improved environmental resilience are desired.

In various embodiments, a VSD material may be incorporated in a flexible circuit (sometimes denoted a “flex circuit”). As defined in the industry standard IPC-T-50 a flexible circuit is “A patterned arrangement of printed wiring utilizing flexible base material with or without flexible coverlayers.” Examples of flexible circuits include wiring structures used to interconnect electronic components (e.g., integrated circuits and semiconductor chips) or circuit elements (e.g., resistors, capacitors, inductors, diodes, transistors). Some flexible circuits are used to make interconnections between other electronic assemblies, either directly or through additional connectors. For example a flexible circuit connector can be used to connect a display to a main PCB board. Optionally portions of the flexible circuit can be made rigid such that integrated circuits and passive components can be mounted onto the flex circuit connector.

A VSD material may be incorporated in a layer of a flexible circuit, and may be used to provide ESD protection to the flexible circuit itself, to circuit elements attached to the flexible circuit or otherwise formed on the flexible circuit, to electronic components attached to the flexible circuit, and/or to other portions of an electronic device in which the flexible circuit is disposed.

In one embodiment, a VSD material is incorporated in a single-sided flex circuit. Single-sided flexible circuits have a single conductor layer made of either a metal or conductive (metal filled) polymer on a flexible dielectric film. Component termination features are only from one side. Holes may be formed in a base film to allow component leads to pass through for interconnection, normally by soldering.

In one embodiment, a VSD material is incorporated in a double access or back bared flex circuit. Double access flex circuits, also known as back bared flex, are flexible circuits having a single conductor layer but which is processed so as to allow access to selected features of the conductor pattern from both sides.

In one embodiment, a VSD material is incorporated in a sculptured flex circuit. Sculptured flex circuits are a type of flexible circuit structures. The manufacturing process of sculptured flex circuits involves a special flex circuit multi-step etching method which yields a flexible circuit having finished copper conductors wherein the thickness of the conductor differs at various places along their length.

In one embodiment, a VSD material is incorporated in a double-sided flex circuit. Double-sided flex circuits are flex circuits having two conductor layers. Theses flex circuits can be fabricated with or without plated through holes, though the plated through hole variation is much more common. An example of a double-sided flex circuit is a “Type V (5)” flex circuit defined according to military specifications.

In one embodiment, a VSD material is incorporated in a multilayer flex circuit. Flex circuits having three or more layers of conductors are known as multilayer flex circuits. Commonly the layers are interconnected by means of plated through holes, though this is not a requirement of the definition for it is possible to provide openings to access lower circuit level features. The layers of the multilayer flex circuit may or may not be continuously laminated together throughout the construction with the obvious exception of the areas occupied by plated through-holes.

In one embodiment, a VSD material is incorporated in a rigid-flex circuit. Rigid-flex circuits are a hybrid construction flex circuit consisting of rigid and flexible substrates which are laminated together into a single structure. The layers of a rigid flex are also normally electrically interconnected by means of plated through holes. Rigid-flex circuits have been used widely in military-grade products and are increasingly being used in commercial products. Rigid-flex boards are normally multilayer structures. Some rigid-flex boards have two metal layers.

In one embodiment, a VSD material is incorporated in a rigidized or stiffened flex circuit. Rigidized or stiffened flex circuit may have one or more conductor layers.

In one embodiment, a VSD material is incorporated in a polymer thick film flex circuit. Polymer thick film (PTF) flex circuits are printed circuits in which conductors are printed onto a polymer base film. PTF flex circuits are may be single conductor layer structures, or may comprise two or more metal layers that are printed sequentially separated by insulating layers. While lower in conductor conductivity, PTF flex circuits have successfully served in a wide range of low power applications at slightly higher voltages. A common application of PTF flex circuits are keyboards.

Applications for flexible circuits comprising VSD materials for ESD protection may include automotive products (e.g., instrument panels, under hood controls, headliner circuits, ABS systems), computers and peripherals (e.g., dot matrix print heads, disk drives, ink jet print heads, printer head cables), consumer products (e.g., digital and video cameras, personal entertainment products, exercise monitors, hand-held calculators), industrial control products (e.g., laser measuring devices, inductor coil pickups, copy machines, heater coils), medical products (e.g., hearing aids, heart pace-makers, defibrillators, ultrasound probe heads), instruments (e.g.;NMR analyzers, X-ray equipment, particle counters, infrared analyzers), telecommunications products (e.g., cell phones, high speed cables, base stations, smart cards and RFID products), military and aerospace products (e.g., satellites, instrumentation panels, plasma displays, radar systems, jet engine controls, night vision systems, smart weapons, laser gyroscopes, torpedoes, electronic shielding technology, radio communications products, surveillance systems).

Embodiments described with reference to the drawings are considered illustrative, and Applicant's claims should not be limited to details of such illustrative embodiments. Various modifications and variations may be included with embodiments described, including the combination of features described separately with different illustrative embodiments. Accordingly, it is intended that the scope of the invention be defined by the following claims. Furthermore, it is contemplated that a particular feature described either individually or as part of an embodiment can be combined with other individually described features, or parts of other embodiments, even if the other features and embodiments make no mentioned of the particular feature.

What is claimed is:

1. A flexible circuit comprising a layer of voltage switchable dielectric (VSD) material, at least a portion of the layer of VSD material being adapted to provide electrostatic (ESD) protection.

2. The flexible circuit of claim 1, wherein the ESD protection is provided to the flexible circuit itself, to at least one circuit element attached to the flexible circuit, to at least one circuit element formed on the flexible circuit, to at least one electronic component attached to the flexible circuit, or to another portion of an electronic device in which the flexible circuit is disposed.

3. The flexible circuit of claim 1, wherein the flexible circuit is a single-sided flex circuit, a double access flex circuit, a or back bared flex circuit, sculptured flex circuit, a double-sided flex circuit, a multilayer flex circuit, a rigid-flex circuit, a rigidized flex circuit, a stiffened flex circuit, or a polymer thick film flex circuit.

4. The flexible circuit of claim 1, wherein the flexible circuit is disposed in an electronic device.

5. The flexible circuit of claim 4, wherein the electronic device is a mobile phone, smartphone, personal communication device, electronic tablet, electronic reader, mobile computer, desktop computer, server computer, television set, video display, music player, personal health management device, light emitting diode (LED), device comprising at least one LED, or lighting module.

6. A flexible substrate comprising a voltage switchable dielectric material formation (VSDM formation) adapted to switch across a gap to provide electrostatic (ESD) protection.

7. The flexible substrate of claim 6, wherein the VSDM formation is a horizontal switching VSDM formation adapted to switch across a horizontal gap formed by the voltage switchable dielectric material, or a vertical switching VSDM formation adapted to switch across a vertical gap formed by the thickness of the voltage switchable dielectric material.

8. The flexible substrate of claim 6, wherein the flexible substrate is a single layer PCB, a multiple layer PCB, a single layer package, a multilayer package of a semiconductor device, a multilayer package of a semiconductor device, an LED substrate, an integrated circuit (IC) substrate, an interposer, a platform that connects two or more electronic components, devices or substrates, a stacked packaging format, a wafer-level package, a package-in-package, a system-in-package, or a stacked combination of at least two packages or substrates.

9. The flexible substrate of claim 8, wherein the flexible substrate is comprised in an electronic device.

10. The flexible substrate of claim 9, wherein the electronic device is a mobile phone, smartphone, personal communication device, electronic tablet, electronic reader, mobile computer, desktop computer, server computer, television set, video display, music player, personal health management device, light emitting diode (LED), device comprising at least one LED, or lighting module.

11. An electronic device comprising a flexible circuit, the flexible circuit comprising a layer of voltage switchable dielectric (VSD) material, at least a portion of the layer of VSD material being adapted to provide electrostatic (ESD) protection to at least a portion of the electronic device.

12. The electronic device of claim 11, wherein the electronic device is a mobile phone, smartphone, personal communication device, electronic tablet, electronic reader, mobile computer, desktop computer, server computer, television set, video display, music player, personal health management device, light emitting diode (LED), device comprising at least one LED, or lighting module.

13. The electronic device of claim 11, wherein the VSD material has (i) a peel strength that is greater than 3, (ii) a coefficient of thermal expansion that is less than or equal to 100, and (iii) a glass transition temperature that is greater than 100 Celsius.
